(19) United States
(12) Patent Application Publication
(10) Pub. No.: US 2026/0157152 A1
(43) Pub. Date: Jun. 4, 2026

(54) DEVICE HAVING DELAMINATION DETECTION AND RELATED METHODS

(71) Applicant: Taiwan Semiconductor Manufacturing Company Limited, Hsin-Chu (TW)

(72) Inventors: Wen-Chien CHANG, Hsinchu City (TW); Chih-Hsuan TAI, Taipei City (TW); Hsiang-Tai LU, Hsinchu County (TW); Wei-Ray LIN, Hsinchu City (TW)

(21) Appl. No.: 18/965,125

(22) Filed: Dec. 2, 2024

(51) Int. Cl. H01L 21/66; H01L 21/48; H01L 21/56; H01L 23/00; H01L 23/31; H01L 23/498; H01L 25/065

(52) U.S. Cl. CPC H10P 74/203; H10P 74/207; H10P 74/273; H10W 70/05; H10W 70/65; H10W 70/685; H10W 74/016; H10W 74/121; H10W 90/00; H10W 72/07236; H10W 90/724

(57) ABSTRACT

A method is provided. The method includes: applying a first voltage to a first test key, the first test key being positioned in a first portion of a first interconnect structure overlying an interposer and underlying an integrated circuit die, the first portion overlapping an opening defined by a plurality of bumps of the integrated circuit die; during applying the first voltage, measuring first electrical resistance of the first test key; in response to the first electrical resistance being below a first threshold value, determining that first delamination is present in the first interconnect structure; and in response to the first electrical resistance exceeding a second threshold value that exceeds the first threshold value, determining that first delamination is not present in the first interconnect structure.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a diagrammatic side view of a device, in accordance with some embodiments.

FIG. 1B illustrates a diagrammatic plan view of an integrated circuit die of the device, in accordance with some embodiments.

FIG. 1C illustrates a diagrammatic plan view of a delamination test and shielding structure of the device, in accordance with some embodiments.

FIG. 1D illustrates a diagrammatic plan view of a delamination test and shielding structure of the device, in accordance with some embodiments.

FIG. 1E illustrates a diagrammatic plan view of a delamination test and shielding structure of the device, in accordance with some embodiments.

FIG. 1F illustrates a diagrammatic side view of a device including a delamination test and shielding structure, in accordance with some embodiments.

FIG. 1G illustrates a diagrammatic side view of a device including a delamination test and shielding structure, in accordance with some embodiments.

FIG. 1H illustrates a diagrammatic side view of a device including a delamination test and shielding structure, in accordance with some embodiments.

FIG. 2A illustrates a diagrammatic side view of determining whether delamination is present, in accordance with some embodiments.

FIG. 2B illustrates a diagrammatic side view of determining whether delamination is present, in accordance with some embodiments.

FIG. 2C illustrates a diagrammatic side view of a frontside delamination test and shielding structure, in accordance with some embodiments.

FIG. 2D illustrates a diagrammatic side view of a backside delamination test and shielding structure, in accordance with some embodiments.

FIG. 3A illustrates a diagrammatic perspective view of a delamination test and shielding structure, in accordance with some embodiments.

FIG. 3B illustrates a diagrammatic side view of the delamination test and shielding structure when delamination occurs, in accordance with some embodiments.

FIG. 3C illustrates a diagrammatic perspective view of the delamination test and shielding structure when delamination occurs, in accordance with some embodiments.

FIG. 4 is a flow diagram illustrating a method, in accordance with some embodiments.

FIG. 5 is a flow diagram illustrating a method, in accordance with some embodiments.

FIG. 6 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, process quality and yield are increasingly sensitive to moisture contamination in layer structures. For example, in chip-on-wafer-on-substrate (CoWoS) devices, moisture between layers of the devices can result in delamination of one or more of the layers. The CoWoS device can include a reconstituted interposer that has molding and silicon and can use polyimide (PM) as a dielectric layer to provide benefits to isolation. However, a “sandwich” package structure of the CoWoS device can aggravate PM moisture outgassing, which results in PM pop-up during a heating process, further resulting in delamination propagation, which increases reliability failures.

To reduce reliability failures, embodiments of the disclosure include delamination detection structures, delamination prevention structures, or both. In some embodiments, a device, which may be a CoWoS device, can include one or more delamination structures, such as a delamination-sensitive test key structure, a delamination dam, a delamination shield ring, combinations thereof, or the like. In some embodiments, the delamination-sensitive test key structure is a delamination dam, delamination shield ring or the like that, in operation, has electrical resistance that is different depending on whether or not delamination is present adjacent thereto. The delamination structure(s) can be positioned overlapping a dummy area of an integrated circuit (IC) die, such as an area of the IC die that is substantially free of connectors (e.g., microbumps) where a redistribution layer (RDL, e.g., a PM layer) is prone to absorbing moisture that results in delamination. In some embodiments, the delamination-sensitive test key structure includes or is the delamination shield ring and is positioned at one or more of a frontside RDL and a backside RDL, which is beneficial to prevent delamination propagation. In operation, the delamination structure(s) can improve yield by reducing delamination propagation. Devices that include the delamination-sensitive test key structure can monitor process performance based on electrical resistance of the delamination-sensitive test key structure.

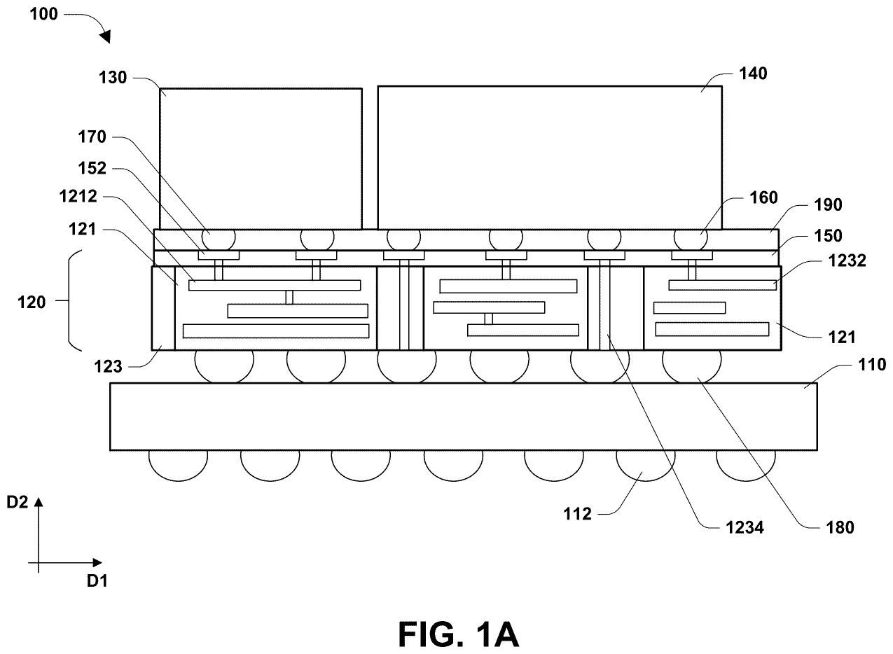

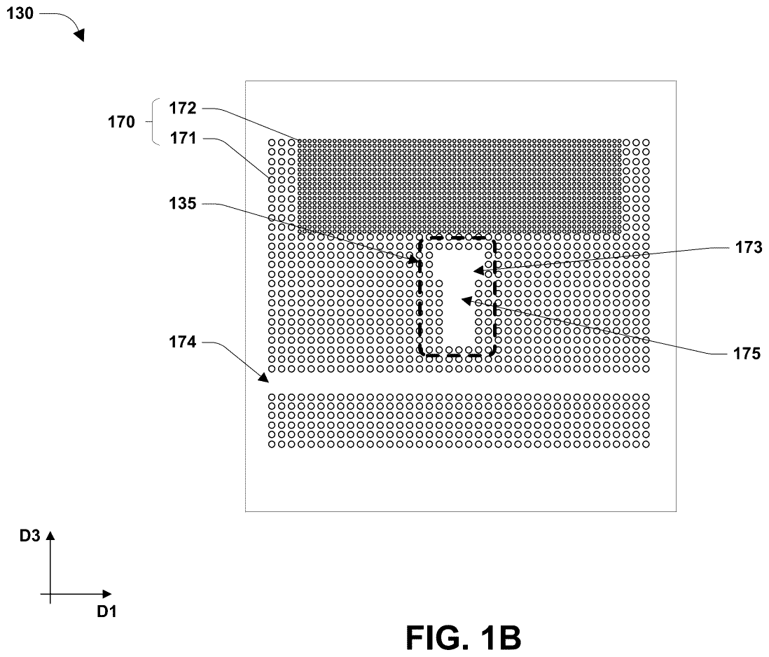

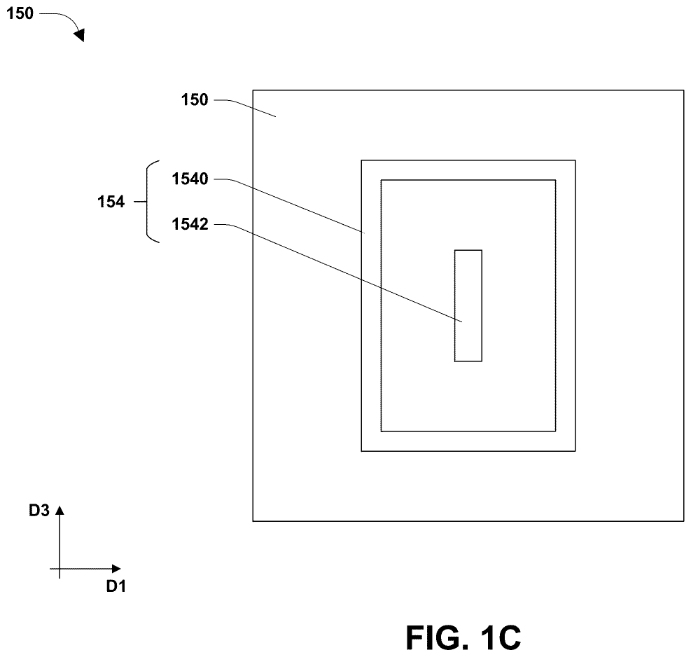

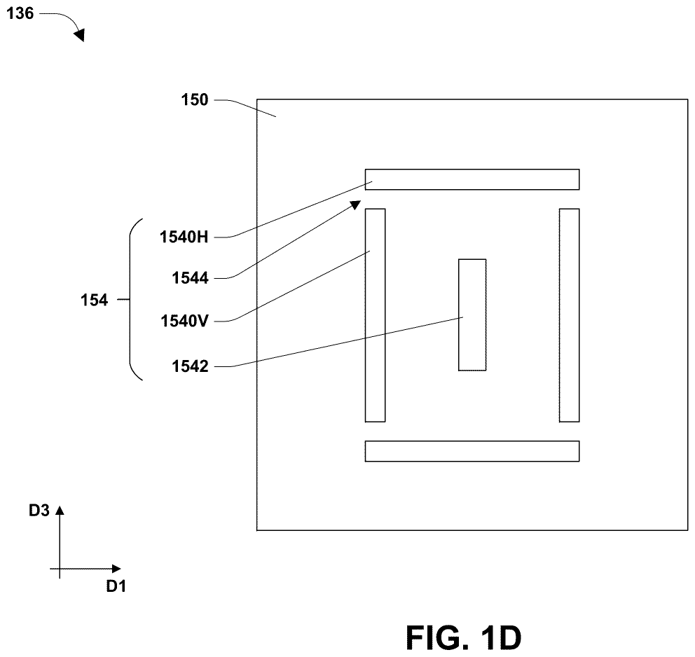

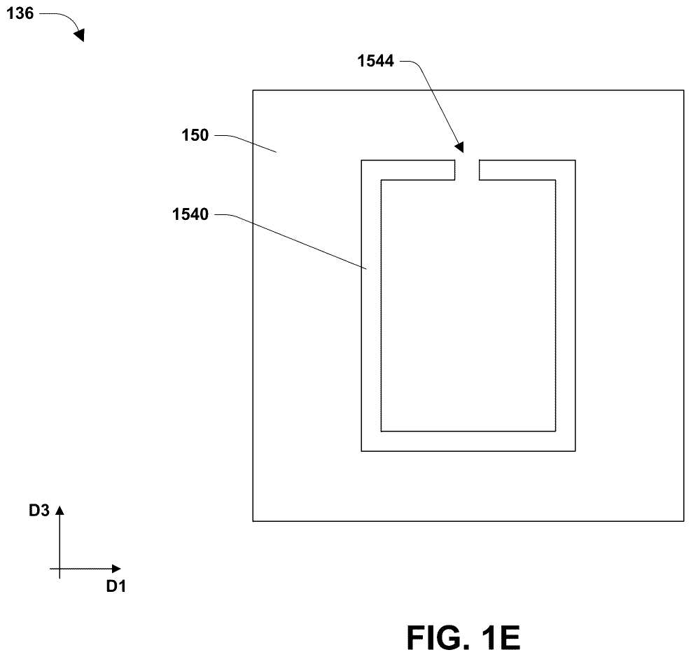

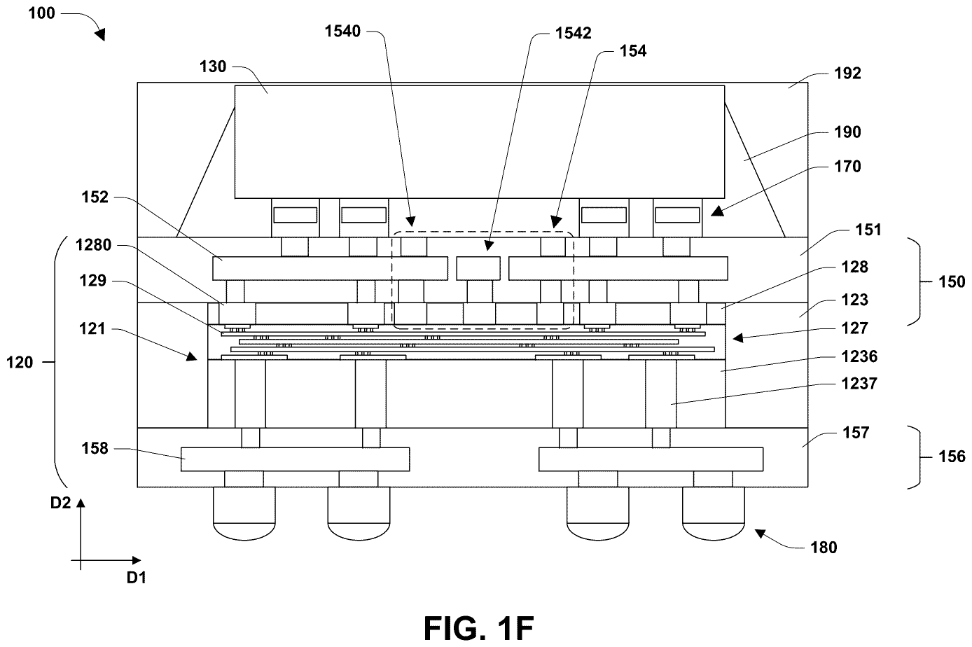

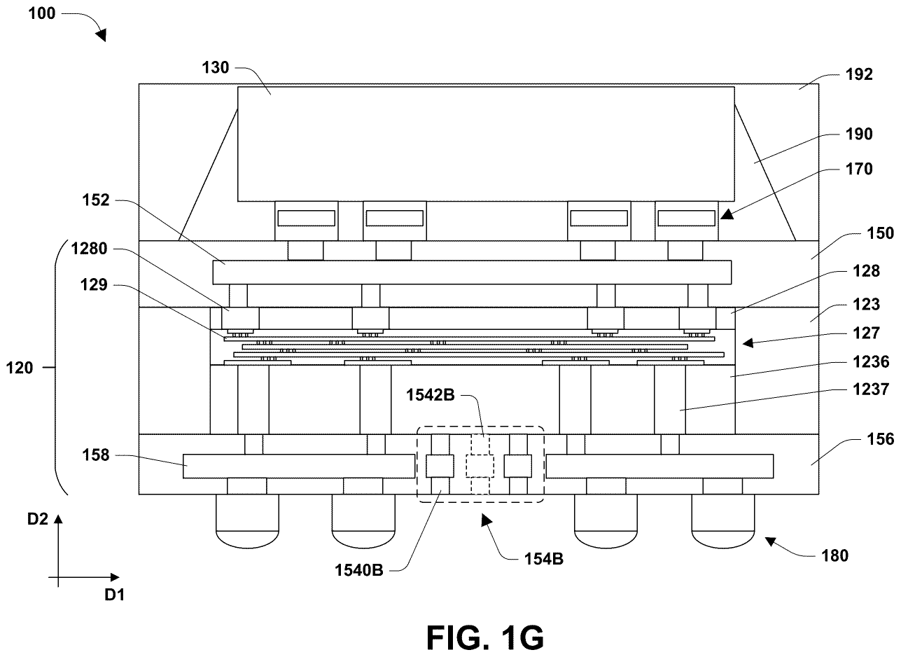

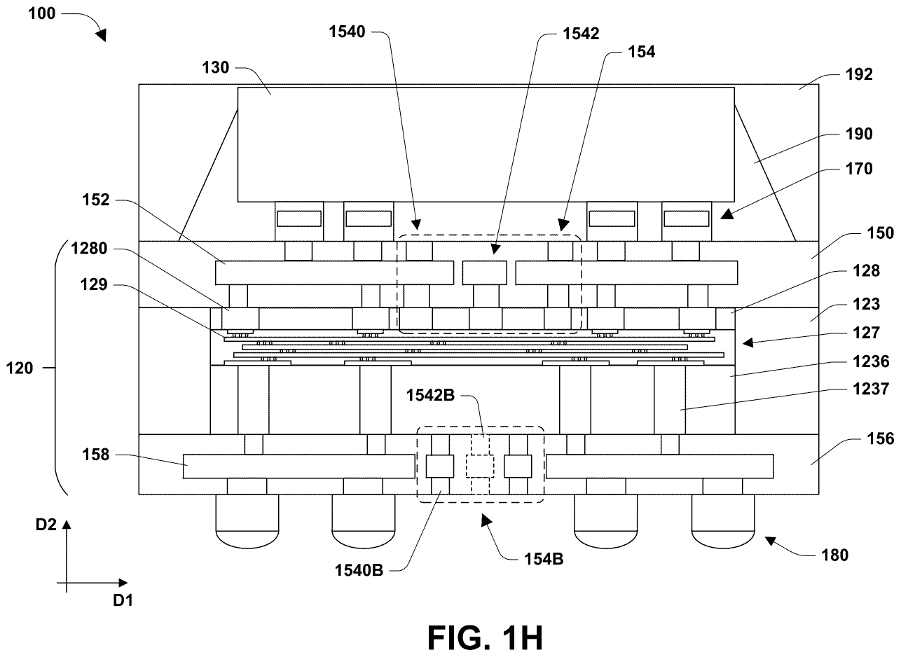

FIG. 1A illustrates a diagrammatic side view of a device 100, in accordance with some embodiments.

The device 100 can be a chip-on-wafer-on-substrate (CoWoS) device 100, an integrated fan-out (InFO) device 100, or the like. In some embodiments, the device 100 includes at least two IC dies 130, 140 that are arranged on a substrate 110, and are electrically connected to each other by an interposer 120 that is positioned between the IC dies 130, 140 and the substrate 110. Each of the IC dies 130, 140 may also be referred to as a “chip.”

A first IC die 130 of the at least two IC dies 130, 140 can be a memory IC die 130, which can be a high-bandwidth memory (HBM) die 130 or the like. The HBM die 130 can be a dynamic random-access memory (DRAM) chip beneficial for high-speed data transfer and efficient power usage in applications such as graphics processing units (GPUs) and artificial intelligence (AI) accelerators. An HBM die stack can include multiple HBM dies or memory layers 130 (e.g., DRAM layers) that are stacked vertically and connected to each other through through-silicon vias (TSVs) for fast, parallel communication. The HBM die 130 can be mounted next to a processor IC 140 (e.g., a GPU, an application processing unit or “APU,” an AI accelerator, or the like) on an interposer or silicon bridge (e.g., the interposer 120), which connects both the HBM die(s) 130 and the processor IC 140. Each HBM die 130 can include memory banks and TSVs, and may be connected electrically to the interposer 120, and optionally to a logic die at the base of the stack, which manages data flow. Structure of the HBM die 130 allows for wide memory buses (e.g., 1024 bits or higher) that provide high bandwidth while reducing power consumption compared to, for example, graphics DDR (GDDR) memory.

A second IC die 140 of the at least two IC dies 130, 140 can be a processor IC die 140, which can be a GPU die 140, an AI accelerator die 140, an APU die 140 or the like. The processor IC die 140, whether a GPU die, AI accelerator die, APU die or the like, can integrate multiple cores and functional circuits onto a single piece of silicon to perform complex computational tasks. The processor IC die 140 can include one or more processing cores (e.g., arithmetic logic units or “ALUs”), cache memory (e.g., L1, L2, and optionally L3), and control circuits, all of which can be interconnected to each other via one or more buses for rapid data transfer. The processor IC die 140 may also include dedicated hardware circuit blocks, such as tensor cores or circuits for AI tasks, single instruction multiple data (SIMD) circuits for parallel processing and the like. I/O controller circuits and memory controller circuits can be included to facilitate communication with external devices and memory. The processor IC die 140 may be fabricated using advanced semiconductor technologies (e.g., fin-type field-effect transistors or “FETs,” nanoscale FETs, or the like) to improve speed, power efficiency, and heat management. The processor IC die 140 can be in data communication with other components via electrical connection to the other components, such as the HBM die(s) 130 or external DRAM, such as via high-speed data interfaces.

The first IC die 130 and the second IC die 140 are positioned on the interposer 120. In some embodiments, the first IC die 130 is connected physically and electrically to the interposer 120 via first bumps 170, which may be microbumps. In some embodiments, the second IC die 140 is connected physically and electrically to the interposer 120 via second bumps 160, which may be microbumps. In some embodiments, a molding compound layer or underfill 190 may be present between the interposer 120 and the first and second IC dies 130, 140. For example, as depicted in FIG. 1A, pads 152 may be positioned in a redistribution layer (RDL) 150 that are in direct contact with the respective first and second bumps 170, 160. The pads 152 can be in electrical connection with first and/or second interconnect metallization layers 1212, 1232 (e.g., metal traces, wires, vias, and the like) of the interposer 120 and/or with through vias 1234 that extend fully through the interposer 120 in a vertical direction D2.

The interposer 120 is positioned between and electrically connected to the substrate 110 and the IC dies 130, 140. In some embodiments, the interposer 120 is a reconstituted interposer (RI) and can be referred to as the RI 120. The interposer 120 can include one or more local Si interconnect (LSI) chiplets 121 and global redistribution layers (RDL) 150 to form the reconstituted interposer 120. The LSI chiplets 121 have benefits of a Si interposer, for example, by including first and/or second interconnect metallization layers 1212, 1232, which may be sub-micron Cu interconnects. The LSI chiplets 121 are separated from each other by a molding compound layer 123, which can also be referred to as an insulator layer 123. The RI 120 includes the through insulator vias (TIVs) 1234 and can optionally include embedded deep trench capacitors (eDTCs) that are beneficial to increase system performance. Through insulator vias (TIVs) 1234 are included in the RI 120 as vertical interconnects to provide a lower insertion loss path than through-substrate vias (TSVs). The TIVs 1234 extend through the insulator layer 123 to connect, for example, one of the second bumps 160 (or one of the first bumps 170) to a third bump 180 of the RI 120. In some embodiments, one or more of the LSI chiplets 121 includes at least one TSV. The third bumps 180 are positioned on an underside of the RI 120 that faces the substrate 110 and form electrical and physical connection between the RI 120 and the substrate 110. In some embodiments, the third bumps 180 are controlled collapse chip connection (C4) bumps.

The substrate 110 can be or include a printed circuit board (PCB). The substrate 110 is connected to the RI 120 via the third bumps 180. In some embodiments, the substrate 110 has a plurality of conductive balls 112 (e.g., solder balls or the like) positioned on the bottom surface thereof. The substrate 110 can be a ball grid array (BGA) circuit substrate, but the disclosure is not limited thereto.

FIG. 1B illustrates a diagrammatic plan view of an integrated circuit die 130 of the device, in accordance with some embodiments. The plan view of FIG. 1B can depict a bottom side of the IC die 130 that faces the interposer 120.

As described with reference to FIG. 1A, the IC die 130 can be an HBM die that includes first bumps 170. The first bumps 170 can include large bumps 171 and small bumps 172, which can be referred to collectively as the bumps 171, 172. Arrangement of the large and small bumps 171, 172 can be along the first direction D1 and a third direction D3 that is transverse the first and second directions D1, D2. The large bumps 171 can have size (e.g., diameter) that exceeds size (e.g., diameter) of the small bumps 172. The small bumps 172 can be arranged having pitch and/or spacing that is smaller than pitch and/or spacing of the large bumps 171. For example, immediately adjacent pairs of large bumps 171 can have first spacing therebetween that exceeds second spacing between immediately adjacent pairs of small bumps 172.

A region 135 of the large bumps 171 can include an opening or “dummy area” or “empty area” 173 that is devoid of first bumps 170. The opening 173 can be positioned near a center 175 of the IC die 130 and may overlap the center 175 of the IC die 130. In some embodiments, the opening 173 has length in the third direction D3 that exceeds width thereof in the first direction D1. The dummy area 173 corresponds to a region of the interposer 120 that is prone to absorbing moisture resulting in delamination, which can be a region that is included in the RDL 150, which is a frontside RDL 150, or in a backside RDL that is on an opposite side of the IC die 130 from the frontside RDL 150. In one example, the dummy area 173 is devoid of first bumps 170 and is not used to make connection to the interposer 120. As such, the corresponding region of the interposer 120 that overlaps the dummy area 173 can be generally devoid of interconnect metallization features that are typically included to make electrical connection with the first bumps 170. This can result in the corresponding region of the interposer 120 being more prone to absorbing moisture and generating delamination, for example, in heating processes.

In some embodiments, the opening 173 has a first dimension along the first direction D1 that exceeds at least about four times the spacing of the large bumps 171. In some embodiments, the opening 173 has second dimension along the third direction D3 that exceeds at least about eight times the spacing of the large bumps 171.

In embodiments of the disclosure, one or more test keys or Kelvin structures can be positioned in the region of the interposer 120 corresponding to the opening 173 to prevent delamination, prevent spread of delamination, and/or determine whether delamination is present. Embodiments of shield test keys 154 are described with reference to FIGS. 1C, 1D, and 1E.

One or more optional openings 174 may be included among the first bumps 170. For example, the opening 174 may extend along the first direction D1 from a first side of the IC die 130 to a second side of the IC die 130 opposite the first side.

FIG. 1C illustrates a diagrammatic plan view of a delamination test and shielding structure or “shield test key” or “test key” 154 of the device 100, in accordance with some embodiments.

In some embodiments, the test key 154 is positioned in the RDL 150, which can be a frontside RDL 150. In some embodiments, the test key 154 is positioned in a backside RDL that is on an opposite side of the LSI chiplets 121 from the frontside RDL 150. In some embodiments, one test key 154 is positioned in the frontside RDL 150 and another test key, which can be similar in many respects to the test key 154, is positioned in the backside RDL.

The test key 154 includes a shield ring 1540 and a line structure 1542 that is surrounded on at least two sides by the shield ring 1540. In some embodiments, the shield ring 1540 is or includes at least two conductive walls. In the embodiment depicted in FIG. 1C, the shield ring 1540 is a closed loop that completely surrounds the line structure 1542 on four sides and has four conductive walls. It should be understood that “surrounds” includes the meaning that the shield ring 1540 surrounds the line structure 1542 on fewer than six sides (e.g., front, back, left, right, top, and bottom). Namely, the shield ring 1540 can laterally surround the line structure 1542 on front, back, left and right sides without surrounding the line structure 1542 on top and bottom sides. The top and bottom sides may face along the second direction D2 that is transverse the first and third directions D1, D3 depicted in FIG. 1C.

FIG. 1D illustrates a diagrammatic plan view of a delamination test and shielding structure or “test key” 154 of the device 100, in accordance with some embodiments.

The test key 154 is similar in most respects to the test key 154 described with reference to FIG. 1C. In the embodiment depicted in FIG. 1D, the shield ring 1540 of the test key 154 includes one or more openings 1544. As such, the shield ring 1540 includes horizontal line structures 1540H that extend along the first direction D1, and includes vertical line structures 1540V that extend along the third direction D3. The openings 1544 may be positioned between the horizontal and vertical line structures 1540H, 1540V along the third direction as depicted in FIG. 1D or along the first direction D1. In the embodiment depicted in FIG. 1D, the shield ring 1540 is not a single, continuous structure, but includes the openings 1544, and partially laterally surrounds the line structure 1542.

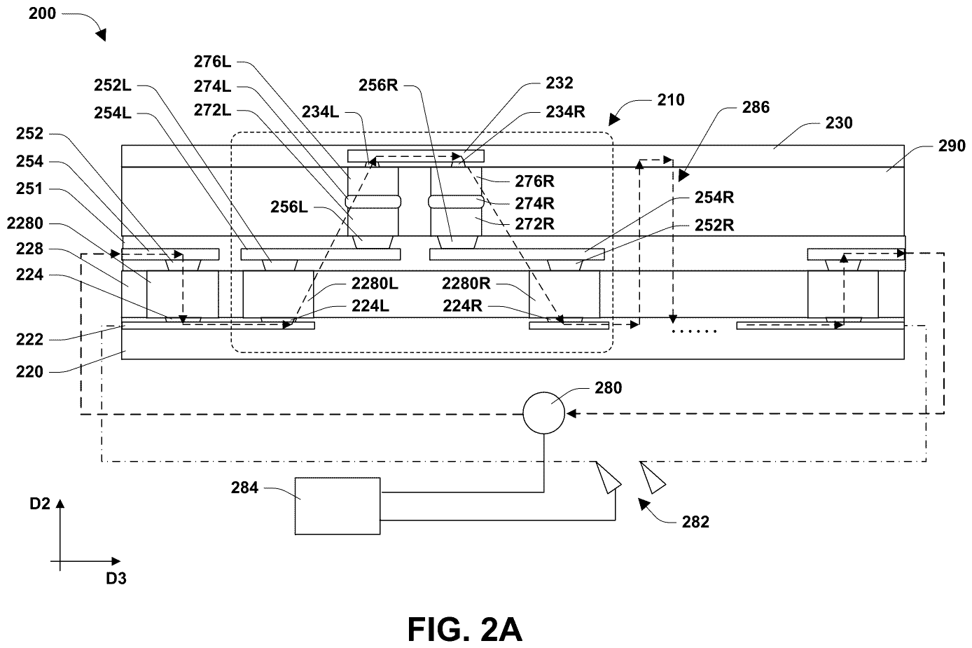

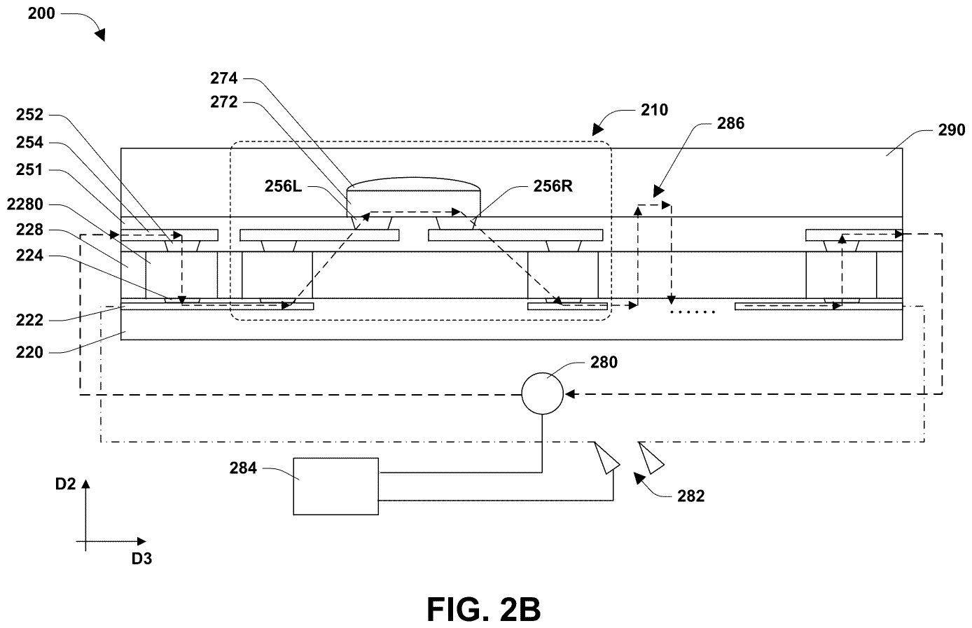

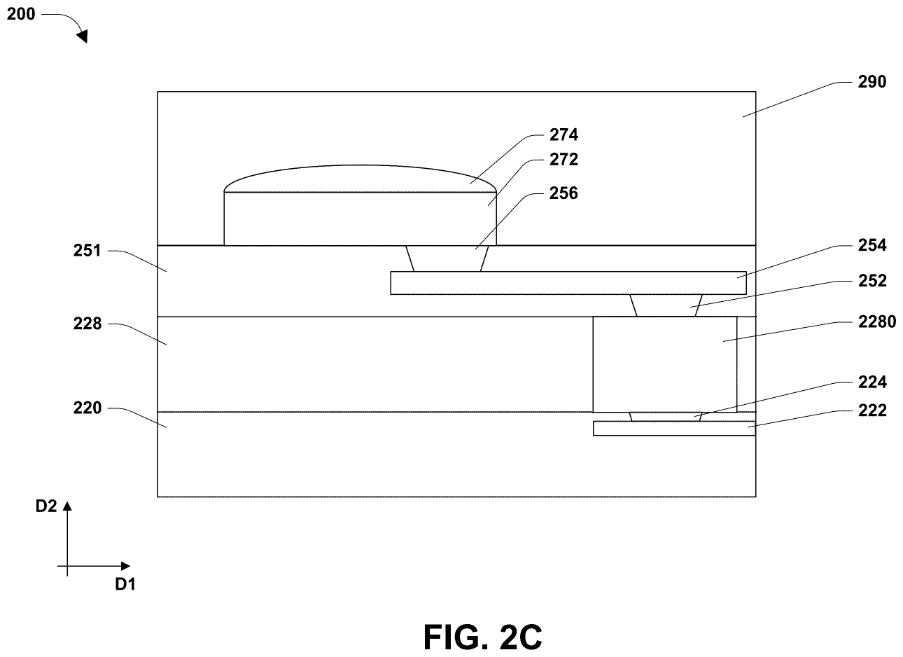

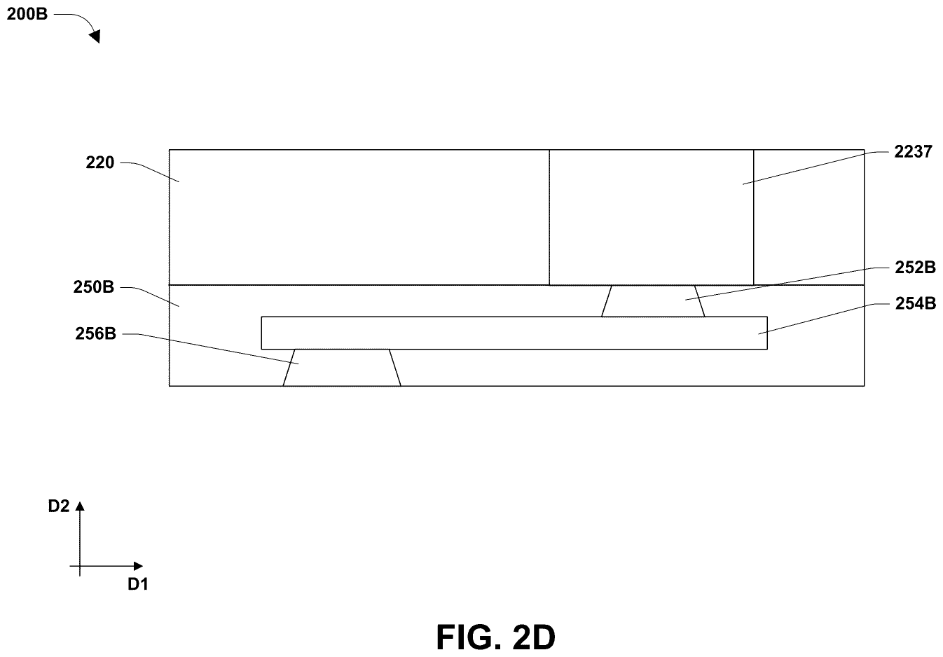

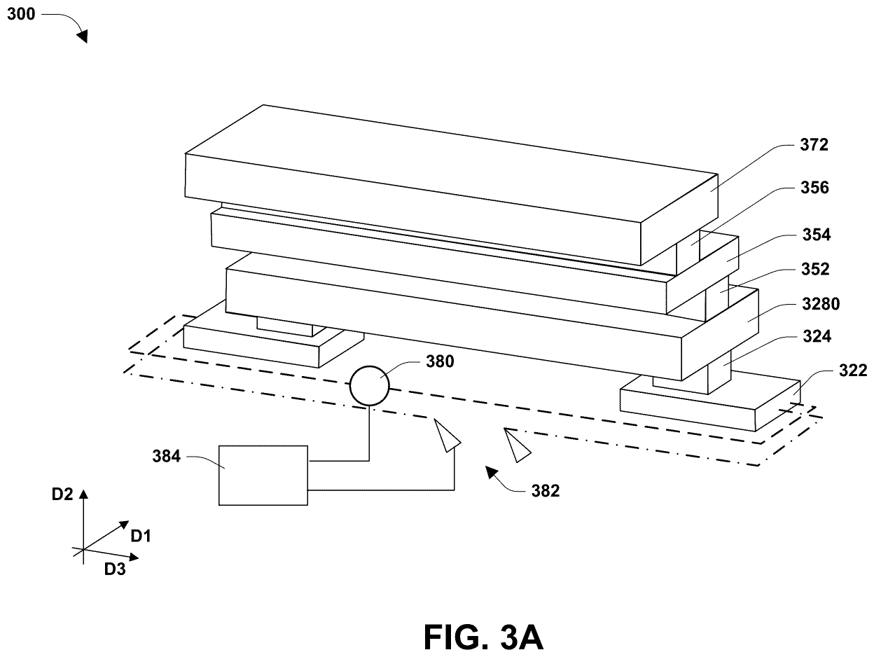

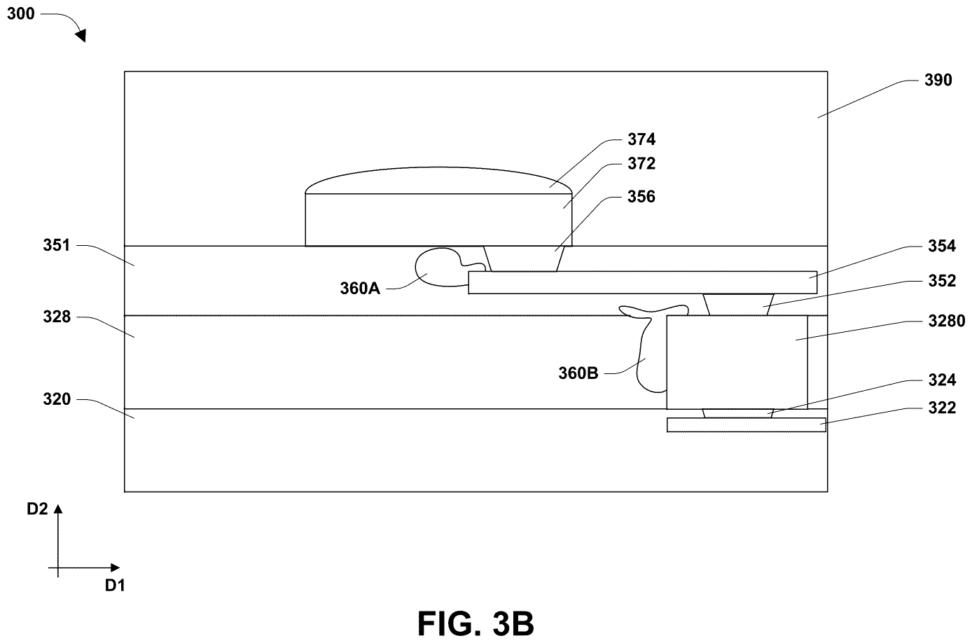

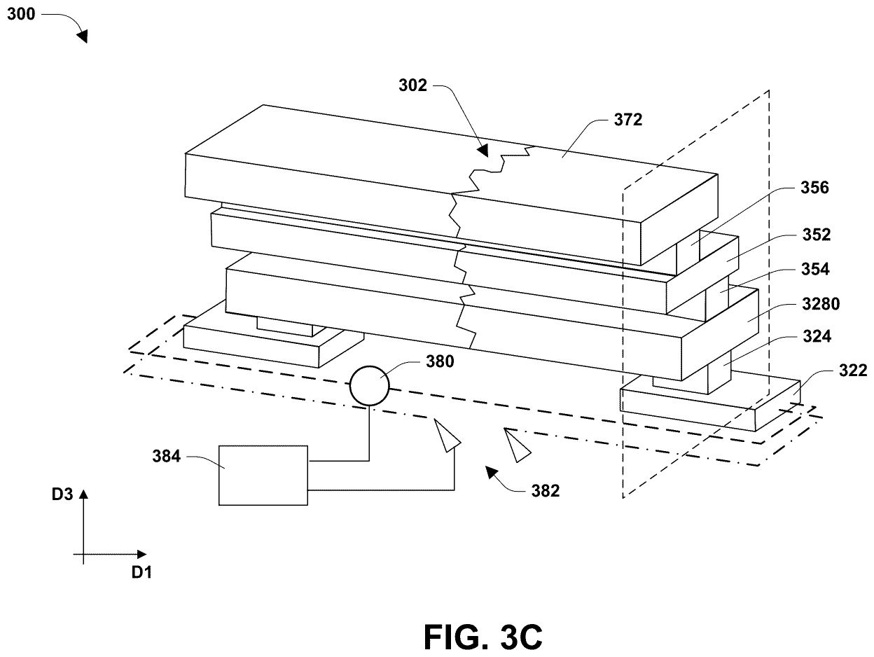

As will be described with reference to FIGS. 2A-3C, the shield ring 1540 is electrically connected to a voltage source and a resistance meter to determine whether delamination is present in the RDL 150. Including the openings 1544 breaks up the shield ring 1540 into the horizontal and vertical line structures 1540H, 1540V, which can each be electrically connected to a voltage source and a resistance meter to determine whether delamination is present in the RDL 150. As a result, the shield ring 1540 of FIG. 1D can provide more granular data about position and spread of the delamination. For example, the delamination may result in a crack in one of the horizontal or vertical line structures 1540H, 1540V and not in others. This can result in improved ability to determine that the delamination is adjacent the one horizontal or vertical Iine structure 1540H, 1540V.

FIG. 1E illustrates a diagrammatic plan view of a delamination test and shielding structure or “test key” 154 of the device 100, in accordance with some embodiments.

The test key 154 is similar in most respects to the test keys 154 described with reference to FIGS. 1C and 1D. In the embodiment depicted in FIG. 1E, the shield ring 1540 of the test key 154 includes a single opening 1544 and does not include the line structure 1542. As such, the shield ring 1540 a single, continuous structure, but includes the opening 1544, and thus does not form a closed loop.

FIG. 1F illustrates a diagrammatic side view of a device 100 including a delamination test and shielding structure or “test key” 154, in accordance with some embodiments.

The device 100 of FIG. 1F is similar in many respects to the device 100 described with reference to FIG. 1A, and like reference numerals refer to like elements. Only a portion of the device 100 is depicted in FIG. 1F, and some portions are omitted from view for clarity of illustration. For example, the IC die 140 and regions of the interposer 120 and molding layer 190 that underlie the IC die 140 are omitted from view. The substrate 110 is also omitted from view in FIG. 1F.

In FIG. 1F, the interposer or “RI” 120 includes an LSI chiplet 121. The LSI chiplet 121 is depicted in detail in FIG. 1F. In some embodiments, the LSI chiplet 121 includes a semiconductor layer (e.g., silicon) 1236 and an interconnect layer 127 positioned on the semiconductor layer 1236. A molding compound layer 123 laterally surrounds the LSI chiplet 121. The combination of the LSI chiplet 121 and the molding compound layer 123 can be referred to as a reconstituted interposer 120.

The semiconductor layer 1236 may also be referred to as the silicon layer 1236. In some embodiments, the semiconductor layer 1236 comprises at least one of a substrate, a semiconductor device, a dielectric layer, an epitaxial layer, a silicon-on-insulator (SOI) structure, a semiconductor layer, a conductive material layer, a die, etc. The semiconductor layer 1236 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor layer 1236 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor layer 1236 are within the scope of the present disclosure.

TSVs 1237 extend through the semiconductor layer 1236. The TSVs are vertical electrical connections that pass through the semiconductor layer 1236. The TSVs 1237 can be beneficial for high-bandwidth, low-latency signal connections between different layers of the LSI chiplet 121 or between different chips in a multi-die package, such as between the LSI chiplet 121 and the underlying substrate 110 or between the substrate 110 and the IC die 130. The TSVs 1237 can be formed by etching deep holes in the silicon layer 1236 and filling the holes with conductive materials, such as copper to form vertical pathways.

The interconnect layer or “interconnect structure” 127 of the LSI chiplet 121 is positioned on the semiconductor layer 1236 between the semiconductor layer 1236 and the IC die 130. The interconnect structure 127 can include at least one dielectric layer in a vertical stack, each of which includes conductive features or “interconnect metallization features” 129 embedded therein. In some embodiments, the conductive features 129 include one or more of conductive lines, conductive traces, conductive vias, combinations thereof, and the like.

The molding compound layer 123 laterally surrounds the semiconductor layer 1236 and the interconnect structure 127 of the LSI chiplet 121. For example, the LSI chiplet 121 may be embedded in the molding compound layer 123. The molding compound layer 123 may be or include an epoxy-based material or other suitable material that provides benefits of improved thermal conductivity, reduced thermal expansion, reduced moisture absorption, and improved mechanical strength. The molding compound layer 123 extends above the interconnect structure 127, such that a first frontside RDL 128 may be positioned on the interconnect structure 127. Upper surfaces of the molding compound layer 123 and the first frontside RDL 128 may be substantially coplanar.

The first frontside RDL 128 is positioned on the interconnect structure 127 and between the molding compound layer 123. The first frontside RDL 128 includes conductive features 1280, which may be conductive vias, conductive pads, or the like. The conductive features 1280 are embedded in an insulator material of the first frontside RDL 128 and may be or include copper or another suitable metal or alloy. The insulator material can be or include polyimide (PI or “PM”), polybenzoxazole (PBO), an epoxy-based dielectric, benzocyclobutene (BCB), combinations thereof, or the like. A single frontside RDL 128 is depicted in FIG. 1F that is positioned between the molding compound layer 123. In some embodiments, two or more frontside RDLs 128 are positioned between the molding compound layer 123.

A frontside RDL structure 150 includes the first frontside RDL 128 and upper frontside RDLs or an “upper frontside RDL structure” 151 that are positioned above the molding compound layer 123. The upper frontside RDLs 151 may be referred to as “global frontside RDLs 151,” as the upper frontside RDLs 151 can extend along the length of the interposer 120 in the first and/or third directions D1, D3. The first frontside RDL 128 may be referred to as a “local frontside RDL 128,” as the first frontside RDL 128 extends along the length of the LSI chiplet 121 and is discontinuous along the length of the interposer 120.

The upper frontside RDL structure 151 may include at least two frontside RDLs, each of which may include one or more conductive features 152 embedded therein. The conductive features 152 may be or include copper or another suitable metal or alloy. Each of the conductive features 152 may be or include a conductive line, a conductive trace, a conductive via or the like.

The test key 154 (or “frontside test key 154”) is positioned in the frontside RDL structure 150 (or “first interconnect structure 150”) and may include conductive features 1280 and conductive features 152. For example, the shield ring 1540 may include an extension of one or more of the conductive features 152 and one or more additional conductive features 152 (e.g., a via, a line or the like) above and below the extension. The line structure 1542 can include a first conductive feature (e.g., a line, a via or the like) in a same layer as one of the conductive features 152 and one or more additional second conductive features (e.g., a via, a line or the like) above and/or below the first conductive feature. The test key 154 is described in greater detail with reference to FIGS. 2A-3C.

The interposer 120 includes a backside RDL structure 156 (or “second interconnect structure 156”) that underlies the semiconductor layer 1236 and the molding compound layer 123. The backside RDL structure 156 can include at least two backside RDLs 157, each of which may include one of the insulator materials described above and may have one or more conductive features 158 embedded therein. The conductive features 158 may be similar in most respects to the conductive features 152 described above.

An encapsulation 192 is positioned on the molding compound layer 190 and between the IC dies 130, 140. The encapsulation 192 can be or include an epoxy molding compound (EMC), a liquid encapsulation, or the like. The encapsulation provides benefits of mechanical protection, moisture resistance, and thermal stability.

FIG. 1G illustrates a diagrammatic side view of a device 100 including a delamination test and shielding structure or “backside test key” or “second shield test key” 154B, in accordance with some embodiments.

The device 100 of FIG. 1G is similar in most respects to the device 100 of FIG. 1F. In some embodiments, the backside test key 154B is positioned in the backside RDL structure 156. The backside test key 154B can include a backside shield ring 1540B and may include an optional backside line structure 1542B depicted in phantom in FIG. 1G. Each of the backside shield ring 1540B and the backside line structure 1542B can include a stack of one or more of the conductive features 158. Embodiments of the backside test key 154B are described in detail with reference to FIGS. 2A-2D.

FIG. 1H illustrates a diagrammatic side view of a device 100 including frontside and backside delamination test and shielding structures or test keys 154, 154B, in accordance with some embodiments.

The device 100 of FIG. 1H is similar in most respects to the devices 100 of FIGS. 1F and 1G. In some embodiments, the device 100 includes the frontside test key 154 and the backside test key 154B.

As depicted in FIGS. 1F-1H, the device 100 can include the frontside test key 154, the backside test key 154B, or both.

FIG. 2A illustrates a diagrammatic side view of determining whether delamination is present, in accordance with some embodiments. A frontside test key portion 200 that is operable to determine whether the delamination is present is depicted in detail in FIG. 2A in accordance with some embodiments. The frontside test key portion 200 can be referred to alternatively as “the test key 200” throughout the description. The frontside test key portion 200 can be an embodiment of the shield ring 1540, the line structure 1542, or both.

The test key 200 includes a repeated unit chain structure that includes at least two unit structures 210. A single unit structure 210 is depicted in FIG. 2A for simplicity of illustration.

In FIG. 2A, the unit structure 210 includes two first conductive lines 222 that are positioned at an upper region of an interposer 220. The interposer 220 is similar in most respects to the interposer 120 described with reference to FIGS. 1A-1H. The first conductive lines 222 can be mostly similar to the conductive features 129 described with reference to FIGS. 1A-1H.

Each of the first conductive lines 222 has a first conductive via 224 positioned thereon. A left first conductive via 224L is positioned on one of the first conductive lines 222 and a right first conductive via 224R is positioned on the other of the first conductive lines 222.

Each of the first conductive vias 224 has a second conductive via 2280 positioned thereon. The left first conductive via 224L has a left second conductive via 2280L positioned thereon and the right first conductive via 224R has a right second conductive via 2280R positioned thereon. The second conductive vias 2280 are embedded in a first frontside RDL 228. The second conductive vias 2280 and the first frontside RDL 228 are similar in most respects to the conductive features 1280 and the first frontside RDL 128 described with reference to FIGS. 1A-1H.

In some embodiments, formation of the first frontside RDL 228 including the second conductive vias 2280 can include a process having a sequence of operations. The process can begin with deposition of a dielectric layer (e.g., polyimide, PBO, or other polymer-based materials) on the surface of a wafer including the LSI chiplet 121 or on the surface of the interposer 220 including the LSI chiplet 121. The dielectric layer provides electrical insulation between metallization layers and serves as a base for an RDL structure of the first frontside RDL 228. The dielectric material may be spin-coated onto the surface and then cured using heat to solidify and adhere the dielectric material to the wafer or interposer 220. The thickness of the dielectric layer can vary depending on selected specifications of the first frontside RDL 228.

Following formation of the dielectric layer, a layer of photoresist may be spin-coated on top of the dielectric layer. The wafer is then exposed to ultraviolet (UV) light through a mask that defines patterns for RDL traces and via openings. After patterning the photoresist, a thin seed layer of metal (e.g., copper or a combination of titanium/copper) is deposited on the exposed surface of the dielectric layer. The seed layer provides an initial conductive layer for a subsequent electroplating process. The seed layer may be deposited via sputtering or physical vapor deposition (PVD).

With the seed layer in place, electroplating is performed to deposit a thicker layer of copper within the patterned trenches and via holes. Thickness of the copper layer can be in a range of about 1 micron to about 100 microns. After the copper is electroplated, the remaining photoresist is stripped away, leaving behind only the electroplated copper that forms the RDL patterns (e.g., traces and vias). In some embodiments, a chemical-mechanical planarization (CMP) operation can be performed to smooth the surface and improve uniformity of thickness across the entire RDL structure.

A similar process to that just described can be performed to form other conductive features in an upper frontside RDL structure 251. The conductive features of the unit structures may be referred to collectively as test conductive features. The test conductive features may be formed using the process just described. During formation of the test conductive features, other conductive features, such as signal conductive features for transmitting data signals and power and ground conductive features for providing power and ground voltages may be formed in the same process operations.

Each of the second conductive vias 2280 has a third conductive via 252 positioned thereon. The left second conductive via 2280L has a left third conductive via 252L positioned thereon and the right second conductive via 2280R has a right third conductive via 252R positioned thereon. The third conductive vias 252 are embedded in the upper frontside RDL structure 251. The third conductive vias 252 and the upper frontside RDL structure 251 are similar in most respects to the conductive features 152 and the upper frontside RDL structure 151 described with reference to FIGS. 1A-1H.

Each of the third conductive vias 252 has a second conductive line 254 positioned thereon. The left third conductive via 252L has a left second conductive line 254L positioned thereon and the right third conductive via 252R has a right second conductive line 254R positioned thereon. The second conductive lines 254 are embedded in the upper frontside RDL structure 251. The second conductive lines 254 and the upper frontside RDL structure 251 are similar in most respects to the conductive features 152 and the upper frontside RDL structure 151 described with reference to FIGS. 1A-1H.

The left second conductive line 254L has a left fourth conductive via 256L positioned thereon and the right second conductive line 254R has a right fourth conductive via 256R positioned thereon. The left and right fourth conductive vias 256L, 256R are embedded in the upper frontside RDL structure 251. The left and right fourth conductive vias 256L, 256R and the upper frontside RDL structure 251 are similar in most respects to the conductive features 152 and the upper frontside RDL structure 151 described with reference to FIGS. 1A-1H. The left and right fourth conductive vias 256L, 256R can also be referred to as left and right metal pads 256L, 256R or “the metal pads 256L, 256R.”

A left copper pillar 272L is positioned on the left fourth conductive via 256L and a right copper pillar 272R is positioned on the right fourth conductive via 256R. The left and right copper pillars 272L, 272R extend above the upper frontside RDL structure 251. A wafer in which the LSI chiplet 121 is formed, which has the metal pads 254L, 254R (e.g., aluminum or copper), can be prepared initially by depositing a passivation layer over the chiplet surface. The passivation layer can be or include silicon nitride or polyimide, and is beneficial to protect the chiplet and expose only the metal pads 254L, 254R where the left and right copper pillars 272L, 272R (or “the copper pillars 272L, 272R”) are to be formed. Before the copper pillars 272L, 272R are formed, a thin layer of under bump metallization (UBM) can be applied to the exposed metal pads 254L, 254R. The UBM can be or include a stack of metals (e.g., Ti/Cu or Ni/Cu) that acts as an adhesion layer between the copper pillars 272L, 272R and the underlying metal pads 254L, 254R. The UBM can be beneficial to improve reliability of interconnection and provide a diffusion barrier. The UBM may be deposited via physical vapor deposition (PVD), in some embodiments. A photoresist layer is then applied and patterned over the wafer, leaving openings where the copper pillars 272L, 272R will be formed. Copper electroplating is then used to fill the openings, forming a cylindrical copper pillar structure. Copper is deposited in the selected shape and height through the electroplating process. In some embodiments, height of the copper pillar is between about 10 μm to about 100 μm, though other heights that are less than or exceed the stated range are also contemplated as embodiments herein.

After the copper pillars 272L, 272R are formed, a thin layer of solder is deposited on tops of the copper pillars 272L, 272R to form solder caps 274L, 274R. The solder caps 274L, 274R may be or include a lead-free alloy such as SnAg and are beneficial to provide a compliant interface for connecting to copper pillars 276L, 276R of an IC die 230. The IC die 230 can be similar in most respects to the IC die 130 described with reference to FIGS. 1A-1H. Once the copper pillars 272L, 272R and solder caps 274L, 274R are formed, the photoresist used to create the pillar pattern is stripped away. Exposed UBM around the copper pillars 272L, 272R is then etched away, leaving only the copper pillars 272L, 272R with their solder caps 274L, 274R on top of the metal pads 254L, 254R.

The copper pillars 276L, 276R of the IC die 230 may be formed by a similar process to that just described with reference to the copper pillars 272L, 272R. For example, the IC die 230 can include a conductive line 232 and left and right metal pads 234L, 234R positioned on the conductive line 232. The copper pillars 276L, 276R can be formed on the metal pads 234L, 234R by forming a dielectric layer, patterning a photoresist layer on the dielectric layer to form openings in the photoresist layer, forming a seed layer in the openings, forming the copper pillars 276L, 276R by copper electroplating on the seed layer, stripping the photoresist and optionally performing a CMP.

The IC die 230 can be mounted to the interposer 220 by aligning the copper pillars 276L, 276R to the copper pillars 272L, 272R, then reflowing the solder caps 274L, 274R to form a strong electrical and mechanical connection between the copper pillars 276L, 276R, 272L, 272R. The left copper pillars 276L, 272L and the left solder cap 274L can be referred to collectively as a first or left microbump. The right copper pillars 276R, 272R and the right solder cap 274R can be referred to collectively as a second or right microbump. Following mounting, an underfill or molding compound layer 290 can be formed between the IC die 230 and the interposer 220. The molding compound layer 290 can be similar in most respects to the molding compound layer 190 described with reference to FIGS. 1A-1H.

Each unit chain 210 can be connected electrically to immediately adjacent unit chains 210 via the first conductive lines 222. Namely, each first conductive line 222 may be electrically connected to two unit chains 210.

To determine whether delamination is present in the upper frontside RDL structure 251, a voltage supply 280 and a resistance meter 282 are electrically connected to the test key 200. The voltage supply 280 and the resistance meter 282 can be controlled by a controller 284 that is in data communication with the voltage supply 280 and the resistance meter 282. In some embodiments, the controller 284 can perform at least one of (i) controlling the voltage supply 280 to apply a voltage to the test key 200, (ii) controlling voltage level of the voltage, (iii) control the resistance meter to read resistance 286 of the test key 200 while the voltage is applied thereto, and (iv) receive electrical resistance data associated with the resistance 286 from the resistance meter. In some embodiments, based on the electrical resistance data, the controller 284 can determine whether a resistance measurement of the electrical resistance data associated with the resistance 286 exceeds a threshold value. In some embodiments, the threshold value is about 10,000 ohms or another suitable value, such that when the controller 284 determines that the resistance of the test key 200 exceeds about 10,000 ohms, determination is made that the delamination occurs. In some embodiments, the threshold value is in a range of about 1,000 ohms to about 100,000 ohms. In response to the resistance measurement exceeding the threshold value, the controller 284 can generate a notification signal. In response to the notification signal indicating that the resistance 286 does not exceed the threshold value, a determination can be made that no delamination is present in the upper frontside RDL structure 251, or that level or degree of delamination present in the upper frontside RDL structure 251 is insufficient to degrade performance of the device 100, for example. In response to determining that delamination is present or is present to a level or degree sufficient to degrade performance of the device 100, the controller 284 may generate an alert signal. In response to the alert signal, the device 100 may be repaired, reworked, scrapped, or the like. For example, the IC dies 130, 140 may be removed from the device 100 to be mounted to another device. In another example, the interposer 120, 220 may be reworked, such as including removing the upper frontside RDL structure 251 and forming a replacement upper frontside RDL structure of the interposer 120, 220.

FIG. 2B illustrates a diagrammatic side view of determining whether delamination is present, in accordance with some embodiments. A frontside test key portion 200 that is operable to determine whether the delamination is present is depicted in detail in FIG. 2B in accordance with some embodiments. The test key 200 of FIG. 2B is similar in most respects to the test key 200 described with reference to FIG. 2A, and like reference numerals refer to like elements. Some elements are not labeled in FIG. 2B for clarity of illustration.

In FIG. 2B, instead of the right and left microbumps that are connected by the conductive line 232 of the IC die 230, each of the unit chains 210 includes a single copper via line 272 having a solder cap 274 thereon. The copper via line 272 is formed on the metal pads 256L, 256R. In some embodiments, the copper via line 272 and the solder cap 274 are physically isolated from the IC die 230 by the underfill 290.

FIG. 2C illustrates a diagrammatic side view of a frontside delamination test and shielding structure 200, in accordance with some embodiments. The view in FIG. 2C depicts a partial view of the test key 200 including the copper via line 272.

In FIG. 2C, the test key 200 includes the first conductive line 222, which may be a top metal line of the LSI chiplet 121 of the interposer 220. The first conductive via 224 is positioned on the first conductive line 222. The second conductive via 2280 is positioned in the first frontside RDL 228 on the first conductive via 224. The third conductive via 252 of the upper frontside RDL structure 251 is positioned on the second conductive via 2280. The second conductive line 254 is positioned on the third conductive via 252. A metal pad 256 that is similar in most respects to the metal pads 256L, 256R described with reference to FIG. 2A is positioned on the second conductive line 254. The copper via line 272 is positioned on the metal pad 256. The solder cap 274 is positioned on the copper via line 272. The underfill 290 covers the upper frontside RDL 251, the copper via line 272 and the solder cap 274.

FIG. 2D illustrates a diagrammatic side view of a portion of a backside delamination test and shielding structure or “backside test key” 200B, in accordance with some embodiments. The backside test key 200B can be an embodiment of the backside shield ring 1540B, the backside line structure 1542B, or both.

The backside test key 200B includes one or more of a TSV 2237, a backside conductive via 252B on the TSV 2237, a backside conductive line 254B on the backside conductive via 252B, and a backside metal pad 256B on the backside conductive line 254B. The TSV 2237 is similar in most respects to the TSV 1237 described with reference to FIGS. 1A-1H. The backside conductive via 252B, the backside conductive line 254B, and the backside metal pad 256B are similar in most respects to the third conductive via 252, the second conductive line 254 and the metal pad 256, respectively, described with reference to FIGS. 2A-2C.

FIG. 3A illustrates a diagrammatic perspective view of a portion of a delamination test and shielding structure or “test key” 300, in accordance with some embodiments. The test key 300 can be an embodiment of the test key 200 described with reference to FIG. 2C.

In FIG. 3A, the test key 300 includes first conductive lines 322, which may be top metal lines of the LSI chiplet 121 of the interposer 220. A first conductive via 324 is positioned on the first conductive line 322. A second conductive via 3280 is positioned on the first conductive via 324. A third conductive via 352 is positioned on the second conductive via 3280. A second conductive line 354 is positioned on the third conductive via 252. A metal pad 356 is positioned on the second conductive line 354. A copper via line 372 is positioned on the metal pad 356. The first conductive lines 322, the first conductive via 324, the second conductive via 3280, the third conductive via 352, the second conductive line 354, the metal pad 356 and the copper via line 372 are similar in most respects to the first conductive line 222, the first conductive via 224, the second conductive via 2280, the third conductive via 252, the second conductive line 254, the metal pad 256 and the copper via line 272, respectively, described with reference to FIGS. 2A-2C.

A voltage supply 380, a resistance meter 382, and a controller 384 are electrically connected to the test key 300. The voltage supply 380, the resistance meter 382 and the controller 384 are similar in most respects to the voltage supply 280, the resistance meter 282 and the controller 284 described with reference to FIGS. 2A-2D.

FIG. 3B illustrates a diagrammatic side view of the delamination test and shielding structure 300 when delamination occurs, in accordance with some embodiments.

In FIG. 3B, the first conductive line 322 and the first conductive via 324 are positioned in an interposer 320, which is similar in most respects to the interposers 120, 220 described with reference to FIGS. 1A-2D. The second conductive via 3280 is positioned in a first frontside RDL 328, which is similar in most respects to the first frontside RDL 228 described with reference to FIGS. 2A-2D. The third conductive via 352, the second conductive line 354 and the metal pad 356 are positioned in an upper frontside RDL structure 351, which is similar in most respects to the upper frontside RDL structures 151, 251 described with reference to FIGS. 1A-2D. An underfill 390 covers the upper frontside RDL structure 351, the copper via line 372 and a solder cap 374 on the copper via line 372. The underfill 390 is similar in most respects to the underfills 190, 290 described with reference to FIGS. 1A-2D. The solder cap 374 is similar in most respects to the solder cap 274 described with reference to FIGS. 2A-2D.

In FIG. 3B, one or more delamination or pop-up regions 360A, 360B are present adjacent the test key 300. The delamination regions 360A, 360B may be a result of moisture that causes outgassing during a heating operation, and may be openings that contain one or more gases (e.g., water vapor), liquids (e.g., water), and the like. In the delamination region 360A, the moisture may be present between two adjacent RDLs of the upper frontside RDL structure 351, resulting in formation of an opening that pushes an upper RDL layer upward, a lower RDL layer downward, or both. In the delamination region 360B, the moisture may be present between the first frontside RDL 328 and a lowermost RDL of the upper frontside RDL structure 351 that is immediately adjacent the first frontside RDL 328, resulting in formation of an opening that pushes the first frontside RDL 328 downward and/or sideways, the lowermost RDL upward, or both.

The delamination regions 360A, 360B exert pressure or strain on the test key 300, which can result in cracking of the test key 300. The cracking increases electrical resistance of the test key 300, which can be detected by the resistance meter 382 and the controller 384.

FIG. 3C illustrates a diagrammatic perspective view of the delamination test and shielding structure 300 when delamination occurs, in accordance with some embodiments.

In FIG. 3C, as just described, one or more delamination regions (e.g., the delamination regions 360A, 360B) present adjacent the test key 300 can exert pressure or strain on the test key 300 that can result in cracking of the test key 300. For example, cracks 302 can form in one or more of the first conductive lines 322, the first conductive via 324, the second conductive via 3280, the third conductive via 352, the second conductive line 354, the metal pad 356 and the copper via line 372. In FIG. 3C, as depicted, the cracks 302 are present in the second conductive via 3280, the third conductive via 352, the second conductive line 354, the metal pad 356, and the copper via line 372. As such, electrical conductivity is reduced or eliminated in the test key 300 due to the cracks 302. Namely, electrical resistance of the test key 300 is increased.

In FIG. 3C, when the resistance of the test key 300 in response to the voltage applied thereto by the voltage supply 380 is measured by the resistance meter 382, the resistance exceeds the threshold value described with reference to FIGS. 2A-2D. Any of the actions described with reference to FIG. 2B can be performed in response to determining that the resistance exceeds the threshold value.

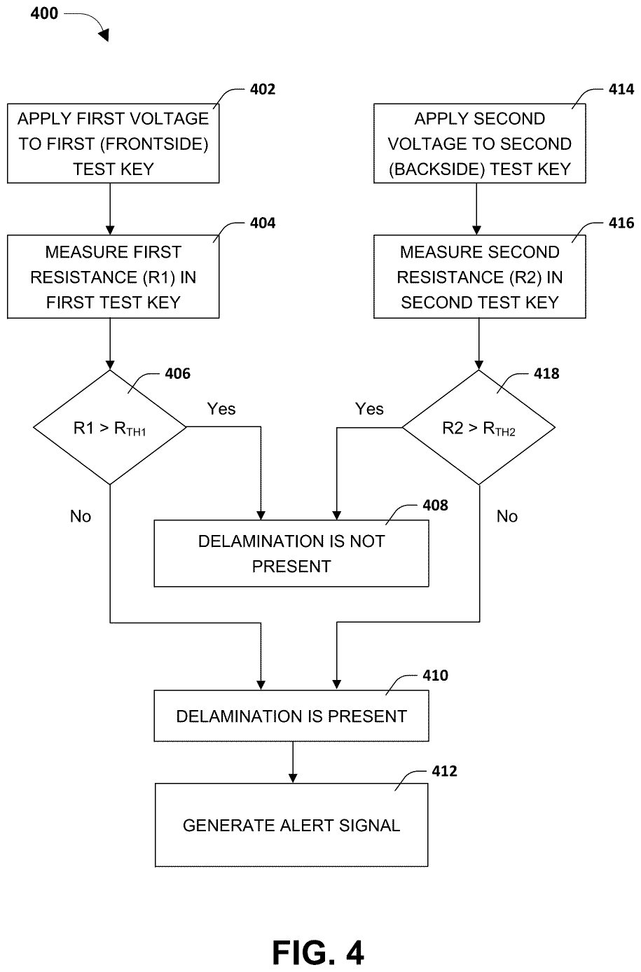

FIG. 4 is a flow diagram illustrating a method 400, in accordance with some embodiments.

A method 400 is illustrated in FIG. 4 in accordance with some embodiments. At 402, the method 400 includes applying a first voltage to a first test key, which may be a frontside test key, such as the test key 200. The first test key is positioned in a first portion of a first interconnect structure (e.g., the RDL 150) overlying an interposer (e.g., the interposer 120) and underlying an integrated circuit die (e.g., the IC die 130). The first portion overlaps an opening defined by a plurality of bumps of the integrated circuit die.

At 404, the method 400 includes during applying the first voltage, measuring first electrical resistance R1 of the first test key.

At 406, the method 400 includes determining whether the first electrical resistance R1 exceeds a first threshold value R_{TH1}. In response to the first electrical resistance R1 exceeding the first threshold value R_{TH1}, the method 400 proceeds to 408. In response to the first electrical resistance R1 not exceeding the first threshold value R_{TH1}, the method 400 proceeds to 410.

At 408, the method 400 includes determining that first delamination is not present in the first interconnect structure.

At 410, the method 400 includes determining that the first delamination is present in the first interconnect structure.

At 412, the method 400 includes generating an alert signal. For example, the controller 284 may generate the alert signal. In response to the alert signal, the device 100 may be repaired, reworked, scrapped, or the like.

At 414, the method 400 includes applying a second voltage to a second test key, which may be a backside test key, such as the backside test key 200B. The second test key is positioned in a second portion of a second interconnect structure (e.g., the backside RDL 156) underlying an interposer (e.g., the interposer 120) and overlying a substrate (e.g., the substrate 110). The second portion overlaps the opening defined by the plurality of bumps of the integrated circuit die.

At 416, the method 400 includes during applying the second voltage, measuring second electrical resistance R2 of the second test key.

At 418, the method 400 includes determining whether the second electrical resistance R2 exceeds a second threshold value R_{TH2}. In response to the second electrical resistance R2 exceeding the second threshold value R_{TH2}, the method 400 proceeds to 408. In response to the second electrical resistance R2 not exceeding the second threshold value R_{TH2}, the method 400 proceeds to 410.

In some embodiments, applying the first voltage to the first test key includes: applying the first voltage to the first test key including a stack of conductive features that extends along a third direction associated with length of the opening.

In some embodiments, the plurality of bumps are arranged according to a spacing and a pitch, and applying the first voltage to the first test key includes: applying the first voltage to the first test key underlying the opening, the opening having first dimension that exceeds at least about four times the spacing.

In some embodiments, applying the first voltage to the first test key includes: applying the first voltage to the first test key underlying the opening, the opening having second dimension that exceeds at least about eight times the spacing, the second dimension being orthogonal the first dimension.

In some embodiments, applying the first voltage to the first test key includes: applying the first voltage to the first test key including a stack of conductive features that has at least one microbump included therein.

In some embodiments, applying the first voltage to the first test key includes: applying the first voltage to the first test key including a stack of conductive features that has at least one via line that extends into an underfill positioned between the first interconnect structure and the integrated circuit die.

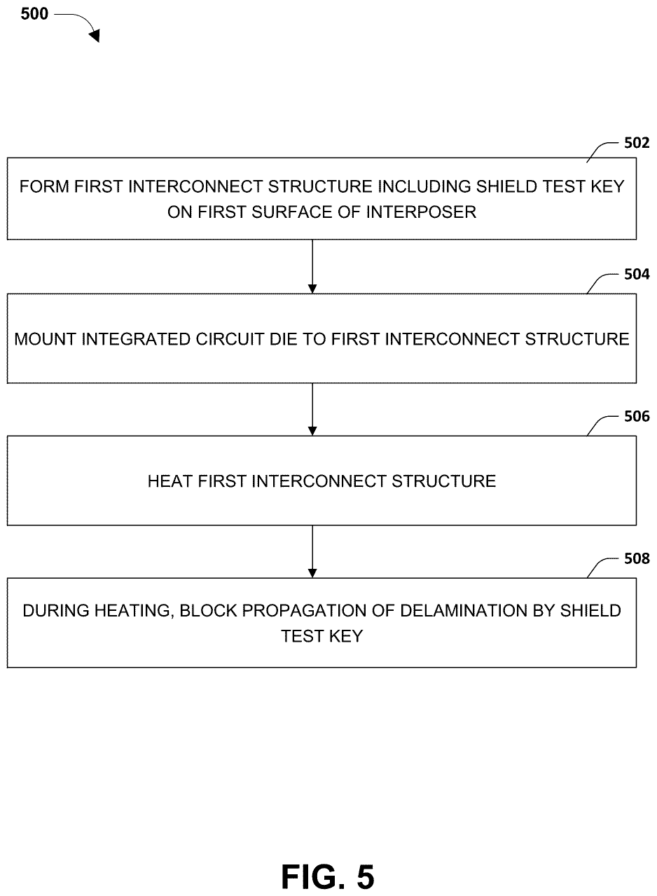

FIG. 5 is a flow diagram illustrating a method 500, in accordance with some embodiments.

The method 500 is illustrated in FIG. 5 in accordance with some embodiments.

At 502, the method 500 includes forming a first interconnect structure (e.g., the frontside RDL structure 150) on a first surface of an interposer (e.g., the interposer 120). The first interconnect structure includes a shield test key (e.g., the test key 154).

At 504, the method 500 includes mounting an integrated circuit die (e.g., the IC die 130) to the first interconnect structure via a plurality of bumps, the plurality of bumps defining an opening (e.g., the opening 173) that overlaps the shield test key.

At 506, the method 500 includes heating the first interconnect structure. The heating can be, for example, during reflowing of solder caps to form microbumps when mounting the IC die to the interposer.

At 508, the method 500 includes during heating the first interconnect structure, blocking propagation of delamination (e.g., the delamination regions 360A, 360B) by the shield test key.

In some embodiments, during blocking the propagation of the delamination by the shield test key, at least one crack is generated in the shield test key. In some embodiments, the method 500 includes detecting presence of the crack by applying a voltage to the shield test key.

In some embodiments, a second interconnect structure is formed on a second surface of the interposer. The second surface faces away from the first surface. The second interconnect structure includes a second shield test key.

In some embodiments, forming the first interconnect structure includes forming the shield test key including a conductive feature that extends above an upper surface of a topmost polymer layer of the first interconnect structure.

In some embodiments, after mounting the integrated circuit die to the first interconnect structure, an underfill is flowed into a space between the first interconnect structure and the integrated circuit die. The underfill can be present between the conductive feature and a surface of the integrated circuit die.

In some embodiments, mounting the integrated circuit die to the first interconnect structure includes forming an electrical connection between at least two microbumps of the conductive feature.

In some embodiments, forming the first interconnect structure including the shield test key includes forming the shield test key that has a Kelvin structure.

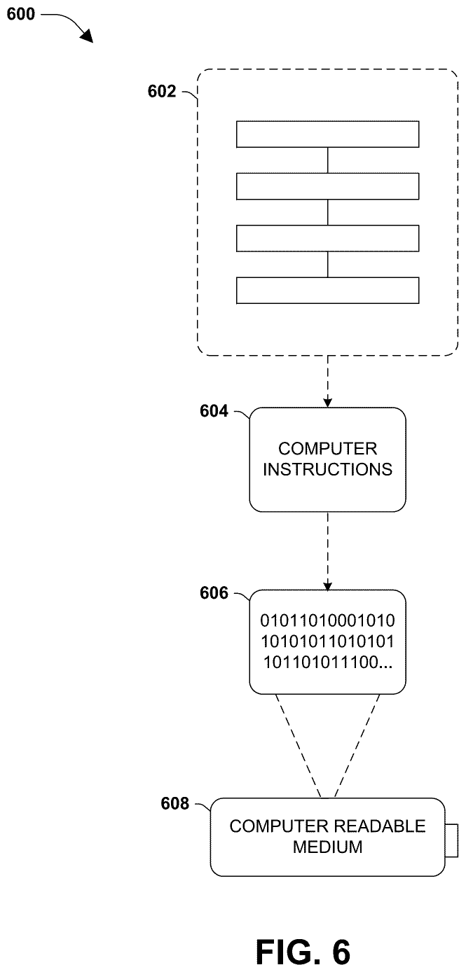

FIG. 6 illustrates an example computer-readable medium wherein processor-executable instructions configured to embody one or more of the provisions set forth herein may be comprised, according to some embodiments.

One or more embodiments involve a computer-readable medium comprising processor-executable instructions configured to implement one or more of the techniques presented herein. An exemplary computer-readable medium is illustrated in FIG. 6, wherein the embodiment 600 comprises a computer-readable medium 608 (e.g., a CD-R, DVD-R, flash drive, a platter of a hard disk drive, etc.), on which is encoded computer-readable data 606. This computer-readable data 606 in turn comprises a set of processor-executable computer instructions 604 configured to implement one or more of the principles set forth herein when executed by a processor. In some embodiments 600, the processor-executable computer instructions 604 are configured to implement a method 602, such as at least some of the aforementioned method(s) when executed by a processor. In some embodiments, the processor-executable computer instructions 604 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a method is provided. The method includes: applying a first voltage to a first test key, the first test key being positioned in a first portion of a first interconnect structure overlying an interposer and underlying an integrated circuit die, the first portion overlapping an opening defined by a plurality of bumps of the integrated circuit die; during applying the first voltage, measuring first electrical resistance of the first test key; in response to the first electrical resistance being below a first threshold value, determining that first delamination is present in the first interconnect structure; and in response to the first electrical resistance exceeding a second threshold value that exceeds the first threshold value, determining that first delamination is not present in the first interconnect structure.

In some embodiments, a method is provided. The method includes: forming a first interconnect structure on a first surface of an interposer, the first interconnect structure including a shield test key; mounting an integrated circuit die to the first interconnect structure via a plurality of bumps, the plurality of bumps defining an opening that overlaps the shield test key; heating the first interconnect structure; and during heating the first interconnect structure, blocking propagation of delamination by the shield test key.

In some embodiments, a device is provided. The system includes: an interposer including a first surface that faces in a first direction and a second surface that faces in a second direction opposite the first direction; a first interconnect structure on the first surface; a second interconnect structure on the second surface; an integrated circuit die on the first interconnect structure and including a plurality of interconnect bumps, an opening being defined in the plurality of interconnect bumps; and a first delamination detection structure positioned in a first portion of the first interconnect structure that overlaps the opening, the first delamination detection structure including a first test key. In operation, the first test key: has a first detection resistance in response to delamination being present in the first portion of the first interconnect structure; and has a second detection resistance that has value exceeding that of the first detection resistance in response to the delamination not being present in the first portion of the first interconnect structure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method, comprising:
applying a first voltage to a first test key, the first test key being positioned in a first portion of a first interconnect structure overlying an interposer and underlying an integrated circuit die, the first portion overlapping an opening defined by a plurality of bumps of the integrated circuit die;
during applying the first voltage, measuring first electrical resistance of the first test key;
in response to the first electrical resistance being below a first threshold value, determining that first delamination is present in the first interconnect structure; and
in response to the first electrical resistance exceeding a second threshold value that exceeds the first threshold value, determining that first delamination is not present in the first interconnect structure.

2. The method of claim 1, comprising:
applying a second voltage to a second test key, the second test key being positioned in a second portion of a second interconnect structure underlying the interposer and underlying the integrated circuit die, the second portion overlapping the opening;
during applying the second voltage, measuring second electrical resistance of the second test key;
in response to the second electrical resistance being below a third threshold value, determining that second delamination is present in the second interconnect structure; and
in response to the second electrical resistance exceeding a fourth threshold value that exceeds the third threshold value, determining that the second delamination is not present in the second interconnect structure.

3. The method of claim 1, wherein applying the first voltage to the first test key includes:
applying the first voltage to the first test key including a stack of conductive features that extends along a third direction associated with length of the opening.

4. The method of claim 1, wherein the plurality of bumps are arranged according to a spacing and a pitch, and applying the first voltage to the first test key includes:
applying the first voltage to the first test key underlying the opening, the opening having first dimension that exceeds at least about four times the spacing.

5. The method of claim 4, wherein applying the first voltage to the first test key includes:
applying the first voltage to the first test key underlying the opening, the opening having second dimension that exceeds at least about eight times the spacing, the second dimension being orthogonal the first dimension.

6. The method of claim 1, wherein applying the first voltage to the first test key includes:
applying the first voltage to the first test key including a stack of conductive features that has at least one microbump included therein.

7. The method of claim 1, wherein applying the first voltage to the first test key includes:
applying the first voltage to the first test key including a stack of conductive features that has at least one via line that extends into an underfill positioned between the first interconnect structure and the integrated circuit die.

8. A method, comprising:
forming a first interconnect structure on a first surface of an interposer, the first interconnect structure including a shield test key;
mounting an integrated circuit die to the first interconnect structure via a plurality of bumps, the plurality of bumps defining an opening that overlaps the shield test key;
heating the first interconnect structure; and
during heating the first interconnect structure, blocking propagation of delamination by the shield test key.

9. The method of claim 8, comprising during blocking the propagation of the delamination by the shield test key, generating at least one crack in the shield test key.

10. The method of claim 9, comprising detecting presence of the crack by applying a voltage to the shield test key.

11. The method of claim 8, further comprising:
forming a second interconnect structure on a second surface of the interposer, the second surface facing away from the first surface, the second interconnect structure including a second shield test key.

12. The method of claim 8, wherein forming the first interconnect structure includes forming the shield test key including a conductive feature that extends above an upper surface of a topmost polymer layer of the first interconnect structure.

13. The method of claim 12, comprising after mounting the integrated circuit die to the first interconnect structure, flowing an underfill into a space between the first interconnect structure and the integrated circuit die, the underfill being present between the conductive feature and a surface of the integrated circuit die.

14. The method of claim 12, wherein mounting the integrated circuit die to the first interconnect structure includes forming an electrical connection between at least two microbumps of the conductive feature.

15. The method of claim 14, wherein forming the first interconnect structure including the shield test key includes forming the shield test key that has a Kelvin structure.

16. A device, comprising:
an interposer including a first surface that faces in a first direction and a second surface that faces in a second direction opposite the first direction;
a first interconnect structure on the first surface;
a second interconnect structure on the second surface;
an integrated circuit die on the first interconnect structure and including a plurality of interconnect bumps, an opening being defined in the plurality of interconnect bumps; and
a first delamination detection structure positioned in a first portion of the first interconnect structure that overlaps the opening, the first delamination detection structure including a first test key, the first test key, in operation:
in response to delamination being present in the first portion of the first interconnect structure, having a first detection resistance; and
in response to the delamination not being present in the first portion of the first interconnect structure, having a second detection resistance that has value exceeding that of the first detection resistance.

17. The device of claim 16, further comprising:
a first delamination prevention structure including at least one first conductive wall adjacent the first test key in the first portion of the first interconnect structure.

18. The device of claim 17, wherein the at least first one conductive wall at least partially surrounds the first test key on at least two sides.

19. The device of claim 16, further comprising:
a second delamination detection structure positioned in a second portion of the second interconnect structure that overlaps the opening, the second delamination detection structure including a second test key.

20. The device of claim 19, further comprising:
a second delamination prevention structure including at least one second conductive wall adjacent the second test key in the second portion of the second interconnect structure.
